(19) United States
(12) Patent Application Publication
(10) Pub. No.: US 2023/0403814 A1
(43) Pub. Date: Dec. 14, 2023

(54) AIR FLOW STRUCTURES FOR CONNECTOR ASSEMBLIES

(71) Applicant: MOLEX, LLC, Lisle, IL (US)

(72) Inventors: Saiyed Muhammad Hasan Ali, Conway, AR (US); Egide Murisa, Little Rock, AR (US); David L. Brunker, Naperville, IL (US)

(21) Appl. No.: 18/033,810

(22) PCT Filed: Nov. 2, 2021
(86) PCT No.: PCT/IB2021/060111

§ 371 Date: Apr. 26, 2023

Related U.S. Application Data
(60) Provisional application No. 63/108,451, filed on Nov. 2, 2020.

(51) Int. Cl. H05K 7/20; H01R 13/6581; H05K 9/00

(52) U.S. Cl. CPC H05K 7/20145; H01R 13/6581; H05K 9/0041

(57) ABSTRACT

A connector assembly may be formed to include a cage, with a connector positioned inside the cage, and an air scooping structure on a side wall of the cage. The air scooping structure is configured to divert a portion of the air flowing along the outside of the cage and re-direct it inward to as to pass by a surface of an inserted module and direct generated thermal energy away from the module. A separate air scooping structure may be formed on each side wall and may include a plurality of individual air scoops disposed in a defined pattern and located in close proximity to any thermal energy-generating areas of the inserted module. A side wall offset may be included along each cage side wall in the area of the included connector to form a wider gap between the connector housing and the cage side wall.

### CROSS-REFERENCE TO RELATED APPLICATION

This application claims priority to U.S. Provisional Application 63/108,451, filed Nov. 2, 2020, which is incorporated herein by reference in its entirety.

### TECHNICAL FIELD

This disclosure relates to the field of connector assemblies for protecting modules from electromagnetic interference (EMI) and, more specifically, to structures for improving air flow through the cage component of these connector assemblies.

### INTRODUCTION

Connector assemblies such as is depicted in FIGS. 1 and 2 are known. The connector assembly includes a cage with walls that defines a port and includes a connector positioned in the cage that has one or more card slots align with the port. The connector assembly can be a stacked design as shown and have two ports that are vertically stacked (along with a corresponding card slot aligned with each port) or could be a single port design. In operation a module is inserted into the port and mates with the connector. The cage helps support the module and also provides EMI shielding.

During high-speed data transmission, especially for modules that are considered active such as electrooptical modules, the module is known to generate thermal energy. Excessive thermal energy can be harmful to the operation of the electronic components provided within the module. While the highest level of EMI protection is provided by a cage formed of continuous metal walls that are coupled to a grounding plane, the lack of vent holes in the cage walls prevents the movement of air and only exacerbates the build-up of thermal energy. Known prior art attempts to minimize the build-up of thermal energy include attaching riding heatsinks to the cage and/or attaching heatsinks to exposed exterior surfaces of the module itself. Exhaust vents may be formed in the front and rear of the cage, but this region is not usually in close proximity to the thermal energy-generating areas within the module.

### SUMMARY

The present disclosure describes air scooping structures that may be incorporated with standard cages of connector assemblies and used to re-direct air flow from an exterior region of a cage to the interior thereof, so that the air passes across a surface of an inserted module and directs any generated thermal energy away from the module. A disclosed cage with improved air flow may be defined as a cage and an associated air scooping structure. The cage includes a pair of opposing side walls and a top wall and typically a bottom wall that cooperatively define a port configured to receive and support an inserted module. A connector positioned in the cage includes a card slot aligned with the port such that a module may be inserted into and mated with the connector card slot. An air scooping structure is formed along an exterior surface of at least one side wall of the cage and is oriented to re-direct a flow of air into the interior volume of the cage so that the air flows across at least one surface of the inserted module, thereby facilitating the removal of thermal energy from the module.

In one embodiment, the air scooping structure may comprise sets of air scoops formed along defined portions of the side walls of the cage. The air scoops may be positioned to be in relatively close proximity to identified thermal energy-generating modules inserted within the cage. The number of individual air scoops and their disposition pattern can vary.

Various configurations of air scooping structures may be used in accordance with the present disclosure to create a path for air to be re-directed to the interior of a cage and pass by inserted electronic components. For example, air scooping structures may take the form of protruding dimples that include an aperture for creating an air transfer channel. Other structures may comprise a combination of a vent hole formed through the thickness of the cage's side wall material and an air capture element positioned over the vent hole. Indeed, an exemplary embodiment comprises the use of an extended-length air diverter that is attached to an exterior surface of a prior art cage structure that has been formed to include EMI-compliant air holes (i.e., relatively small holes that do not seriously degrade the necessary EMI shielding properties of the grounding structure).

In addition to the cages as described above, an embodiment of the present disclosure relates to a connector assembly for housing a connector and providing an air flow path across a portion of a module when the module is inserted in the cage. In this embodiment, the connector assembly may include a cage and an air scooping structure, where the cage may include a pair of opposing side walls and a top wall that cooperatively define port configured to receive and support an inserted module. In operation, a module can be inserted into the port so that the module mates with a connector positioned in the cage. The disclosed air scooping structure may be formed along an exterior surface of at least one side wall at a location adjacent to the port and oriented to re-direct a flow of air into the interior of the cage so as to flow across at least one surface of the inserted module and facilitate the removal of thermal energy from the module.

Yet further, another embodiment of the present disclosure may take the form of a connector assembly comprising a cage formed to define two separate ports, each port for receiving a separate module. In this embodiment, the associated air scooping structure may include at least a first set of air scoops positioned adjacent to a first port and a second set of air scoops positioned adjacent to a second port, providing air flow across the modules inserted in each port.

An alternative embodiment of a multi-port cage and connector assembly may further comprise a cage offset to which is attached an additional exhaust mechanism that allows for air to flow between the cage walls and the connector.

Another connector assembly embodiment of the present disclosure may take the form of a cage similar to any of the other embodiments, with a connector positioned within the cage. This connector assembly embodiment exhibits improved exhaust ventilation by including an offset formed along each cage side wall in the area where the connector is positioned, the offset creating a gap between the side wall and the connector housing that improves air flow through the connector assembly. Alternatives of this embodiment may utilize any of the disclosed air scooping arrangements with the side wall offsets.

The above features and advantages as well as others will be apparent from the following detailed description and the accompanying drawings.

### BRIEF DESCRIPTION OF THE DRAWINGS

The present disclosure is illustrated by way of example and not limited to the accompanying figures in which like reference numerals refer to like elements and in which:

FIG. 1 illustrates a typical prior art cage assembly.

FIG. 2 illustrates another typical prior art cage assembly.

FIG. 3 is a perspective side view of a cage including air scooping structures formed within regions of the cage side walls that would be in proximity to thermal energy-generating areas of inserted modules.

FIG. 4 is a close-up view of a portion of FIG. 3, showing an exemplary configuration of air scooping structures as including a vent hole covered by an air capture element.

FIG. 5 is a close-up side view of a side wall of a cage, illustrating another exemplary type of air scooping structure, in this case comprising a plurality of protruding dimples that are formed to include an aperture to form an air transfer channel.

FIG. 6 is a simplified diagram of a top view of an exemplary cage, illustrating two different geometries of the air capture element as shown in FIG. 4, in one case exhibiting a non-overlapping arrangement with the vent hole and in another case exhibiting an overlapping arrangement with the vent hole, where the overlapping arrangement may be formed to provide additional EMI shielding at certain frequencies.

FIG. 7 is a perspective side view an exemplary cage configured to include a pair of stacked ports for support a stacked arrangement of modules, illustrating the inclusion of air scooping features on each cage side wall in proximity both the top port location and the bottom port location.

FIG. 8 is a close-up view of an exemplary air scooping feature that may be used as part of the cage of FIG. 7.

FIG. 9 is a simplified perspective view of a cage formed to include EMI-compliant air holes but without the air scoops.

FIG. 10 is a simplified perspective view an exemplary cage formed to include the disclosed air scooping structure by modifying the prior art configuration of FIG. 9, in this case including the provision of an air diverter over each grouping of the EMI-compliant air holes.

FIG. 11 is a close-up view of an exemplary air diverter as used in the arrangement of FIG. 10, showing in particular the use of a top plate of a length L that extends across a complete arrangement of air holes.

FIG. 12 is a perspective side view of an exemplary cage formed to include air diverters as shown in FIG. 10, this exemplary embodiment showing the inclusion of a pair of ports for supporting modules and an air transfer channel formed between the two ports, as well as a heat sink positioned over the top module to further facilitate the removal of thermal energy from the arrangement.

FIG. 13 is a simplified top view of the exemplary embodiment of FIG. 12, in this case showing an example of a staggered disposition of the air diverters on the side walls of cage.

FIG. 14 is a simplified top view of a ganged arrangement of cages including the staggered air diverters of FIG. 12, illustrating the ability to increase the depth of the diverters and/or decrease the inter-cage spacing by virtue of staggering the location of the diverters.

FIG. 15 is a perspective side view of an exemplary cage including raised pocket regions formed along selected portions of the cage side walls, where the disclosed air scooping structures are formed within the pocket regions.

FIG. 16 is a close-up view of one exemplary raised pocket region, showing the use of protruding dimples and small vents to provide air flow in accordance with the principles of the present disclosure.

FIG. 17 is a close-up view of an alternative embodiment of a raised pocket region, in this case including an air scooping structure in the form of several air diverters, as well as a set small vents similar to those of FIG. 16.

FIG. 18 contains temperature plots of cage top surfaces that illustrate improvement in thermal transport, where FIG. 18(a) is surface plot associated with the prior art cage of FIG. 9, and FIG. 18(b) is a surface plot associated with a cage formed as shown in FIG. 10.

FIG. 19A is a schematic representation of a module, showing the location of locations where temperatures values can be taken.

FIG. 19B is a table of data associated temperatures taken at points illustrated in FIG. 19A, providing a thermal performance comparison between the prior art and FIG. 3 cage configurations.

FIG. 20 is a surface plot of air flows for a set of three cages disposed in a ganged arrangement, with each cage formed to include staggered air diverters, as depicted in FIG. 14.

FIG. 21 is a surface plot of air flows for a similar set of ganged cages, in this case formed to include the additional pockets with air diverters, as depicted in FIG. 15.

FIG. 22 includes a pair of air flow surface plots, the surface plot of FIG. 22(a) associated with a prior art connector assembly and indicating the location of air flow blockage (i.e., a “choke point”) at the location where the connector housing is positioned essentially against the cage side walls, and the surface plot of FIG. 22(b) associated with a connector assembly formed in accordance with the present disclosure to include offsets within the cage side walls in the area of the connector housing to create a gap between the side walls and the housing, improving the air flow along an exhaust path.

FIG. 23 is an isometric side view of an exemplary connector assembly formed to include side wall offsets, the offsets formed to include a number of vent holes.

FIG. 24 is another isometric side view of the connector assembly of FIG. 23, in this case with the rear of the assembly positioned at the front of the view.

FIG. 25 is a cut-away view of the connector assembly of FIG. 23, showing in particular individual components of the connector itself, as well as the increase in spacing between the connector housing and the cage provided by the side wall offsets.

FIG. 26 is a close-up view of a portion of FIG. 25, denoting the additional gap d created along each side wall in the vicinity of the connector housing.

FIG. 27 is an isometric side view of another configuration of a cage that is formed to include a pair of side wall offsets.

FIG. 28 is a view from the rear face of the cage of FIG. 27, showing the offset d (typically measured in millimeters (mm)) attributed to the inclusion of the side wall offsets.

FIG. 29 is a plot illustrating thermal improvement associated with a bottom port in a stacked port arrangement as a function of gap size d.

FIG. 30 is an isometric view of another connector assembly include side wall offsets, in this case the offsets being solid plates (i.e., “closed”, with no side air holes).

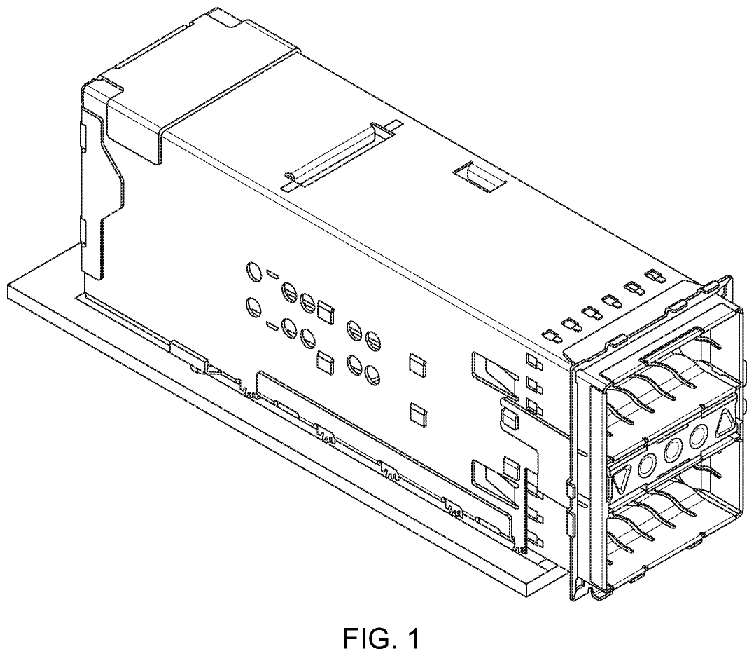

### DETAILED DESCRIPTION, INCLUDING EXEMPLARY EMBODIMENTS

Simplicity and clarity in both illustration and description are sought to effectively enable a person of skill in the art to make, use, and best practice embodiments disclosed herein in view of what is already known in the art. One skilled in the art will appreciate that various modifications and changes may be made to the specific embodiments described herein without departing from the spirit and scope of the disclosure. Thus, the specification and drawings are to be regarded as illustrative and exemplary rather than restrictive or all-encompassing, and all such modifications to the specific embodiments described herein are intended to be included within the scope of the disclosure. Yet further, it should be understood that the detailed description that follows describes exemplary embodiments and is not intended to be limited to the expressly disclosed combination(s). Therefore, unless otherwise noted, features disclosed herein may be combined together to form additional combinations that were not otherwise described or shown for the purposes of brevity. Moreover, the terms “embodiment” or “exemplary” means an example that falls within the scope of the disclosure.

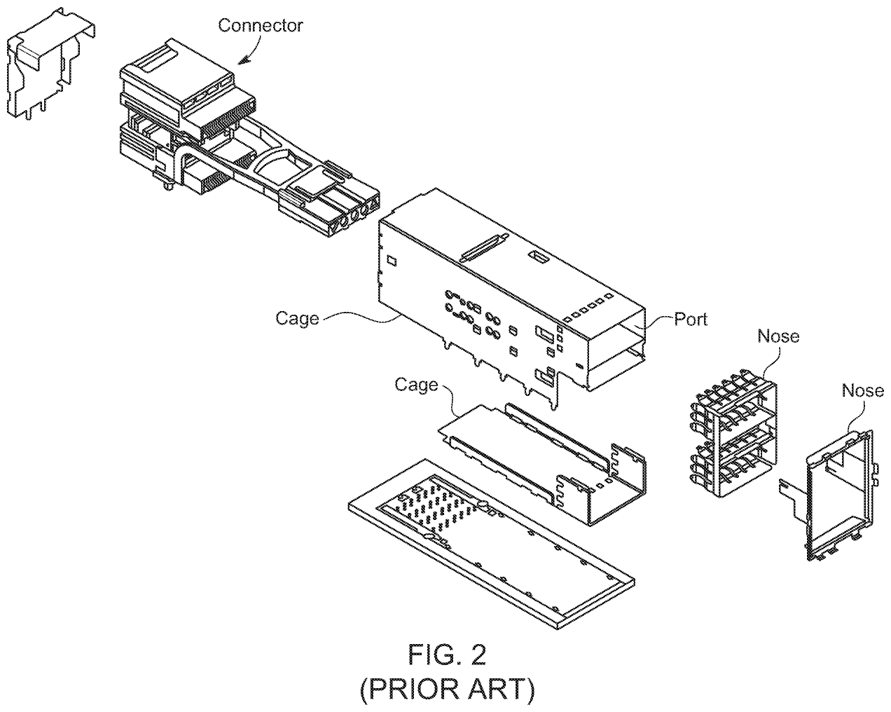

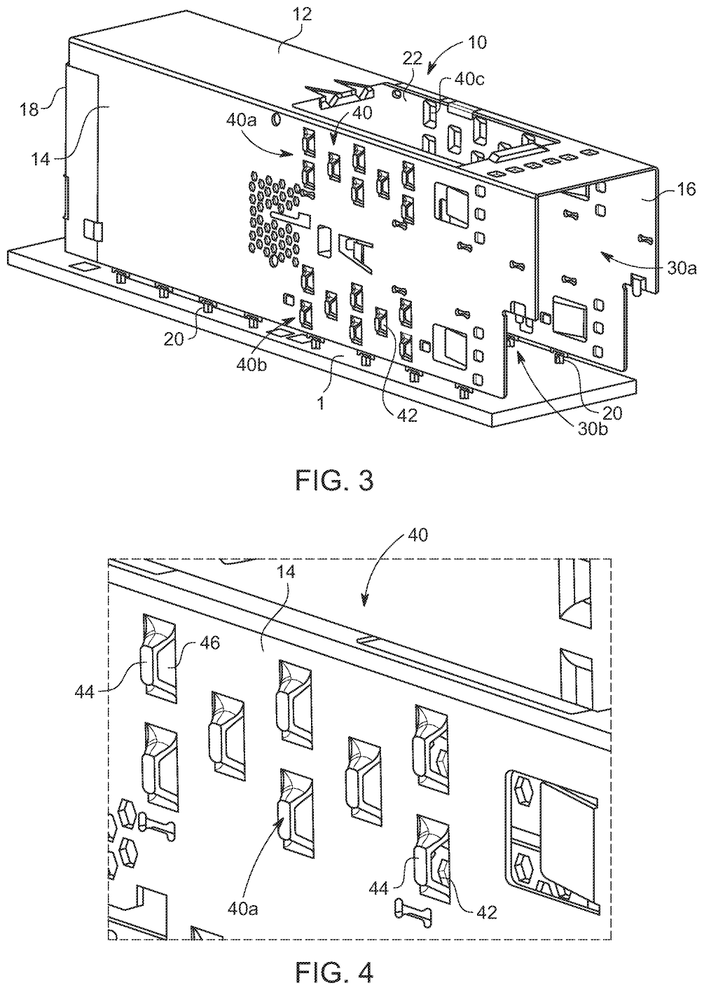

FIG. 3 illustrates an exemplary cage 10 component of a connector assembly that is formed in accordance with the present disclosure to facilitate air flow through the cage while still providing a level of EMI shielding as needed for supporting GHz transmission rates. While only the cage 10 is depicted, a corresponding connector assembly would include a connector, such as the connector shown in FIG. 2. Cage 10 is depicted as having a top wall 12 and a pair of side walls 14, 16 that are joined to form an inverted U-shaped cage with a partially enclosed interior volume. A rear wall 18 may be included and may “wrap around” side walls 14, 16 for stability purposes. Side walls 14, 16 may include tail portions 20 in the form of compliant pins that are received within vias, or other openings, on an associated circuit board 1 (which can formed by any desirable type of construction) so as to connect cage 10 to ground circuits on circuit board 1. An opening 22 in top wall 12 may be included and used to allow for placement of a heat sink that may sit over a module positioned within the interior volume of cage 10. In the embodiment of FIG. 3, the partially enclosed interior volume of cage 10 is configured to include an upper port 30A and a lower port 30B, where a separate module may be inserted within each port.

In order to facilitate air flow through cage 10, a plurality of air scoops are added to side walls 14, 16 and used to re-direct air flowing along the exterior of cage 10 into an interior region in the vicinity of inserted modules. Air flow that would otherwise flow over the cage surface is diverted by thrusting a collecting aperture (the “scoop”) directly into the air flow that is normally channeled between cages to divert a portion of that air flow into the cage to pass over selected heat generating surfaces that are within the cage. The diverted passage of air flow along surfaces of thermal energy-generating modules serves to effectively cool the modules and direct the thermal energy away from their vicinity. A thermal energy transfer path may include a heat sink disposed on an upper surface of cage 10, exhaust vents formed on rear wall 18, or any other suitable arrangement well-known in the art. In the particular configuration as shown in FIG. 3, a plurality of air scoops 40 are shown as formed in selected regions of side walls 14, 16 that are likely to be in proximity to inserted modules (not shown). Air scoops 40 are oriented such that their open faces 46 (shown in detail in FIG. 4, for example) are positioned in a direction to capture the flow of ambient air (or other gas) in the local environment of cage 10. Based on this orientation, air scoops 40 may thus be used to divert air flowing across the exterior surface of side walls 14, 16 and re-direct the air flow inward to facilitate thermal energy transfer away from the inserted modules and thereafter outward via a heat sink and/or exhaust vents (if included). It has been found that positioning air scoops 40 in the vicinity of a thermal energy-generating portion of the inserted module may be preferred for efficient thermal energy transfer away from the module.

In an exemplary embodiment as shown in FIG. 3, a first grouping of air scoops 40a may be positioned along an upper region of side wall 14 so as to be adjacent to an module that would be inserted within upper port 30A of cage 10. A second grouping of air scoops 40b may be positioned along a lower region of side wall 14 so as to be adjacent to another module that would be inserted within lower port 30B. Similarly, a third grouping of air scoops 40c may be positioned along opposing side wall 16 in the area of upper port 30A. While not evident in the view of FIG. 3, a fourth grouping of air scoops 40d may be positioned along side wall 16 in the area of lower port 30B.

FIG. 4 is an enlarged view of air scoops 40a, as formed in a portion of side wall 14 adjacent to upper port 30A region of cage 10. Arrows are included to indicate the re-direction of air flow from the exterior of side wall 14 to the interior thereof by virtue of the presence of the air scoops. In the embodiment as shown in FIG. 4, each air scoop 40 includes a vent hole 42 that is formed as an aperture through the thickness of side wall 14. An air capture member 44 is positioned over vent hole 42, with an opened endface 46 of air capture member 44 oriented such that some of the air flowing along cage 10 will be diverted and directed to the enclosed interior volume of cage 10. The number of individual air scoops included in each set is considered as a matter of design choice, as is the particular distribution pattern of the air scoops on the surface of side wall 14.

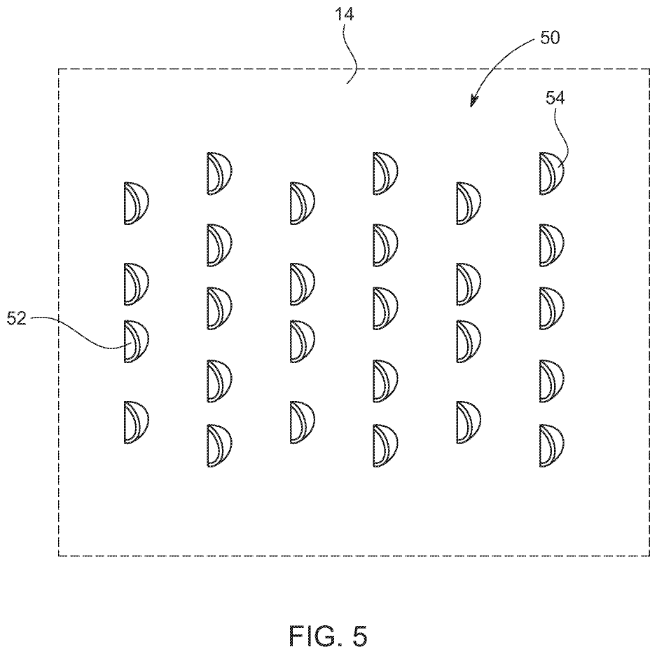

The particular configuration of air scoop 40 as shown in FIG. 4 is considered as only one embodiment of an air scooping structure formed in accordance with this disclosure. For example, FIG. 5 illustrates a plurality of protruding dimples 50 that may be used as the disclosed air flow structure and included on cage side walls 14, 16 to re-direct air flow in the same manner as air scoops 40. Each dimple 50 includes an aperture 52 formed through a portion of the rounded protrusion to provide an air channel into the associated cage. Dimples 50 may be formed using well-known machining operations on the conductive sheet material used to form side walls 14, 16, with the location and size of apertures 52 controlled with similar processes. Again, the size, number and pattern of protruding dimples 50 as used on any particular cage are considered as application-specific design choices.

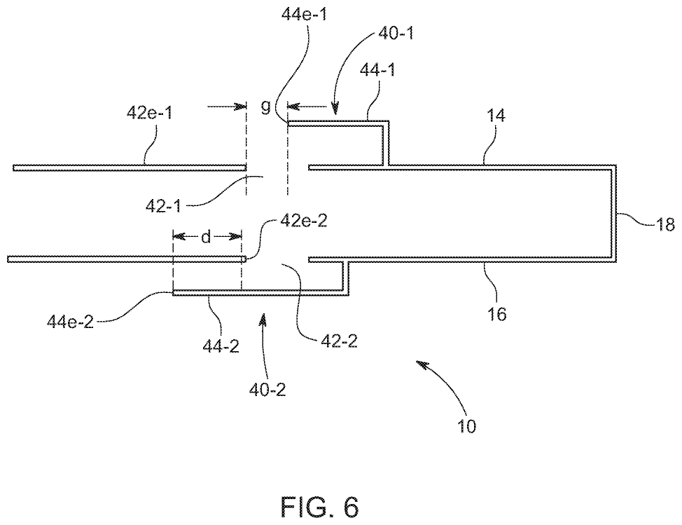

It is also possible to configure the disclosed air scooping structure in a manner that provides an additional degree of EMI filtering at certain frequencies. Reference is made to FIG. 6 to illustrate this concept. In particular, FIG. 6 is a top view of cage 10 in simplified, diagrammatic form with illustrated air scoops 40 not shown to scale. In this example, a first air scoop 40-1 is formed within side wall 14 and a second air scoop 40-2 is formed within side wall 16. Air scoop 40-1 is shown as having a simple, non-overlapping geometry between air capture member 44-1 and vent hole 42-1. The non-overlapping geometry is defined by a gap g between a front edge 44e-1 of air capture member 44-1 and a front edge 42e-1 of vent hole 42-1. The presence of this exposed air hole may somewhat diminish the strength of the EMI shielding, as is known in the art. In contrast, air scoop 40-2 as formed on side wall 16 is configured to exhibit an over-lapping geometry. Here, a front edge 44e-2 of air capture member 44-2 extends to overlap front edge 42e-2 of vent hole 42-2 by an amount d. The overlap, distance d establishes a waveguide cutoff filter formed with the conductive bounding sheet metal surface 16 and conductive scoop surface 44-2. The attenuation level of the overlapping scoop filter is increased proportional to the overlapping distance d. The lower cutoff frequency of the overlapping scoop filter is set by the largest opening size of the scoop mouth. In this manner the cutoff frequency occurs when the maximum height or width of the aperture or scoop opening is approximately equal to a half-wavelength of the impinging electromagnetic field. Therefore, the vent hole 42-2 helps define and creates an EMI filter defined by the overlap d in combination with the surface area created by air capture member 44-2.

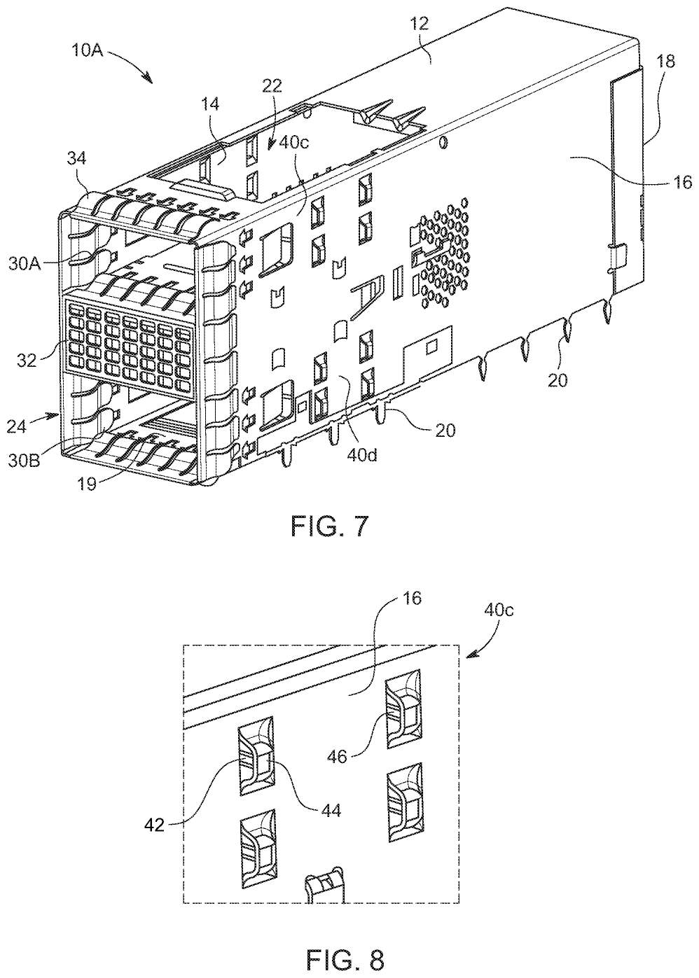

FIG. 7 is an isometric side view of another exemplary cage 10A including an air scooping structure formed in accordance with the present disclosure to facilitate air flow through cages in a manner that improves thermal energy transfer away from inserted modules. Similar to cage 10 of FIG. 3, cage 10A includes top wall 12, side walls 14, 16, and (perhaps) rear wall 18. Additionally, cage 10A includes a base wall 19, connected to the other walls to form an enclosure with an open face 24. Base wall 19 may also include tails 20 that extend into a grounding structure on a supporting substrate (such as a circuit board, not shown). Also similar to cage 10, cage 10A may be formed to support a stack of modules and in this case is shown as including upper port 30A and lower port 30B. In this particular embodiment, cage 10A may be formed to include an air transfer channel structure 32 that is positioned between upper port 30A and lower port 30B. Channel structure 32 may comprise various types of thermal channels well-known in the art to assist in air flow along the interface between upper port 30A and lower port 30B from open face 24 toward rear wall 18.

The arrangement of FIG. 7 may also include a gasket 34 that encircles open face 24 and provides additional EMI protection when cage 10A is mounted to a circuit board and bevel, or cover plate (not shown) is attached to cage 10A. Evident in this side view of cage 10A is a possible location of a set of air scoops 40c as formed in side wall 16 and positioned in an upper section of side wall 16 so as to be adjacent to an module that may be located in upper port 30A. An additional set of air scoops 40d is similarly formed within a lower section of side wall 16 and positioned to direct an air flow into lower port 30B. Scoops 40 as shown in FIG. 7 are shown in enlarged form in FIG. 8 and may be formed in the manner shown in FIG. 4, comprising a vent hole 42 and an air capture member 44, with open face 46 of air capture member 44 positioned to collect air passing along an exterior surface of side wall 16 and direct the air into ports 30 so as to flow along an inserted module and direct thermal energy away from the module. Scooping features such as protruding dimples 50, or any other suitable type of air flow diverting element, may be used as an alternative air flow structure, if desired.

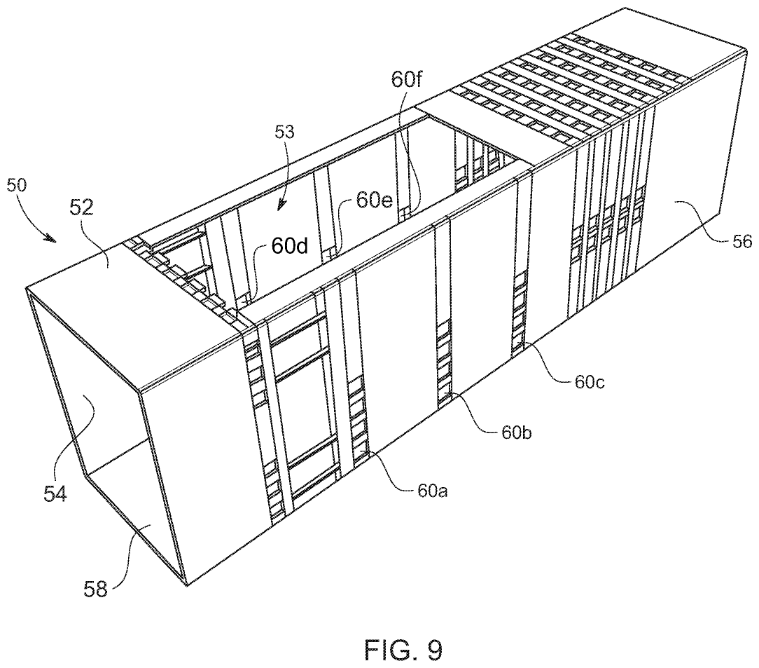

In further accordance with the present disclosure, it is also possible to modify an existing cage to incorporate the disclosed air scooping structure and improve thermal energy transfer away from inserted modules. FIG. 9 is a simplified diagram of a cage configuration 50 prior to installation of an scops, which in this case is formed to include a top wall 52 (with an opening 53 for locating a heat sink), a pair of side walls 54, 56, and a base wall 58, the combination defining a partially enclosed interior volume that may be used to house one or more modules. Thermal management in this arrangement is provided by sets of EMI-compliant air holes 60 formed along each side wall 54 and 56. In the view of FIG. 9, three sets of air holes 60a, 60b, and 60c disposed in linear arrangements are shown. While the inclusion of air holes 60 (which may be formed by stamping cut-outs in the conductive material used to form cage structure 50) may allow for some ambient thermal energy to “escape”, there is no dynamic flow created that may encourage additional thermal energy transfer.

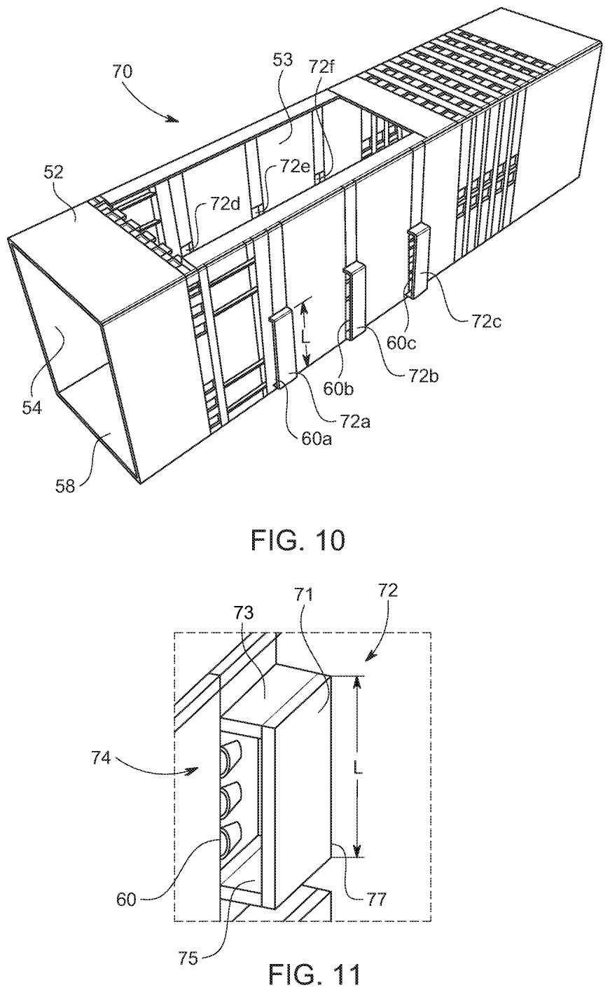

FIG. 10 illustrates a cage 70 that modifies the structure shown in FIG. 9 to provide dynamic air flow capability. As shown, cage 70 is formed to include a set of air diverters 72 that are positioned over EMI-compliant air holes 60 so that passing air may be captured and directed from the exterior of cage structure 70 into the partially enclosed interior volume area in a similar manner as discussed above. In one embodiment, air diverters 72 may be attached to the side of the cage through a desirable technique, such as spot-welding, the use of an adhesive, or other desirable approach to attach the air diverters to a cage to improve the thermal properties of the cage. In an example embodiment, an individual air diverter 72i may be sized to span across a linear set of air holes 60, allowing for air flow to be efficiently re-directed from the exterior of cage 70 through the complete set of air holes 60. As depicted in FIG. 11, an exemplary air diverter 72 may be formed to include a top plate 71, side plates 73 and 75, and a rear plate 77. As discussed above, top plate 71 may have a length L sufficient to span a complete set of air holes as presented in a linear configuration (see FIG. 9). Inasmuch as air diverter 72 includes an open end face 74, any air flow passing along a cage side wall may be captured by air diverter 72 and directed through air holes 60 to provide dynamic thermal energy transfer.

The particular embodiment as shown in FIG. 10 is based upon the design shown in FIG. 9, with air diverters 72 attached to side walls 52,54 and arranged such that a separate air scoop 72i is positioned over an associated linear set of air holes 60. Looking at both FIGS. 9 and 10, a first air diverter 72a is attached to side wall 56 and positioned to span over a first set of air holes 60a. Similarly, a second air diverter 72b is attached to side wall 56 so as to cover a second set of air holes 60b and a third air diverter 72c over air holes 60c. While not shown in this view, an additional set of air diverters 72d, 72e, and 72f can be attached to opposing side wall 52 and positioned over similar sets of air holes 60. Thus, a cage can have one or both sides adapted to improve thermal performance.

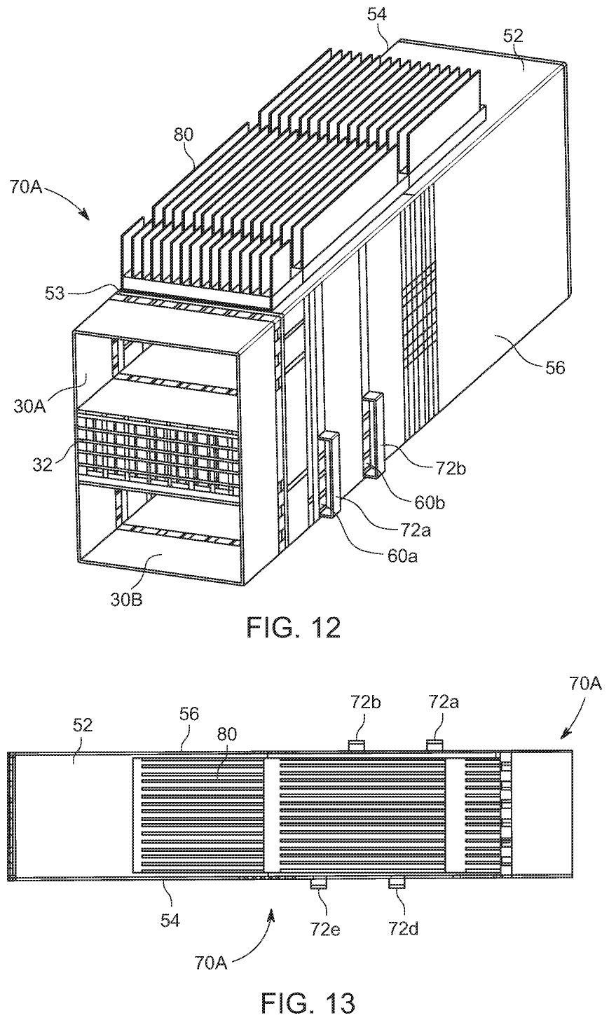

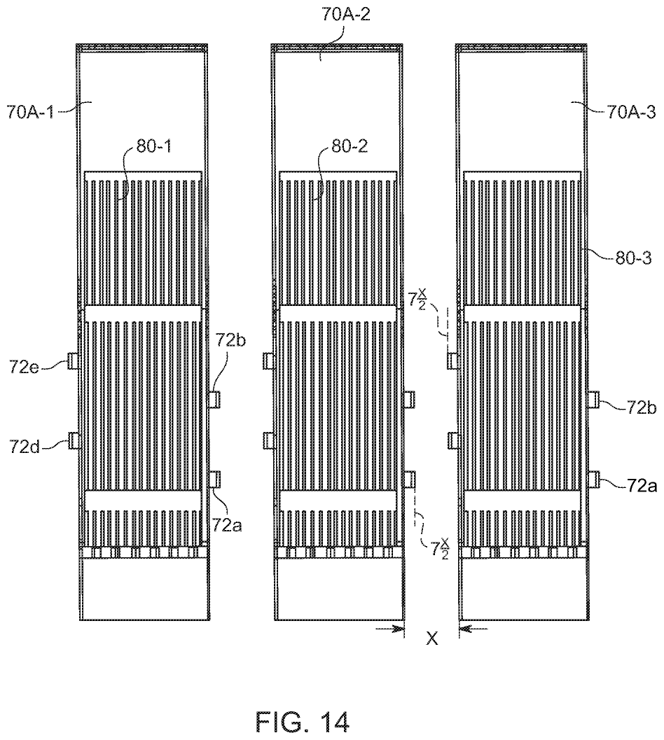

FIG. 12 illustrates a particular embodiment of cage 70A including air diverters 72 as discussed above. In this embodiment, cage 70A is formed to include upper port 30A and lower port 30B, separated by air transfer channel 32. Also shown here is a typical heat sink structure 80 that may be positioned within opening 53 of top wall 52 of cage 70A to provide an efficient thermal energy transfer path for the structure. FIG. 13 is a top view of the arrangement of FIG. 12, and shows an exemplary embodiment of the disclosure where the position of the air holes 60/diverters 72 may be “staggered” (i.e., offset) along one side wall with respect to the other so as to enhance air flow through the cage and to allow similar cages to be mounted next to each other without the diverters from one cage being in an interference condition with diverters in a second adjacent cage. In particular, air diverter 72d (formed along side wall 54) is shown as positioned to be offset with respect to the location of air diverter 72a along side wall 56. It is to be understood that the underlying air holes 60d and 60a are similarly offset. Likewise, air diverter 72e is offset with respect to air diverter 72b. As can be appreciated, for a specific distance between two adjacent cages, the use of staggered air diverters 72 allows for the use of deeper diverters, which capture more air flow than shallow elements. FIG. 14 is a top view of a set of three such cages 70A-1, 70A-2 and 70A-3, disposed in a side-by-side arrangement. Such a side-by-side arrangement of cages is well-known in the art and is commonly used in boxes (such as switches and servers) where an increased number of connectors is useful. By staggering the locations of air diverters 72 on the opposing side walls 54, 56 of each cage, the air diverters on one cage will also be offset from the air diverters on the sidewall of the adjacent cage so that the cages themselves may be positioned relatively close together without their respective air scoop structures coming into physical contact. Moreover, as mentioned above, the staggered arrangement allows for relatively deeper diverters 72 to be utilized. Referring to FIG. 14, presuming adjacent cages are separated by a spacing x, diverters 72 may be formed to have a height slightly greater than x/2 (as long as their positions are staggered).

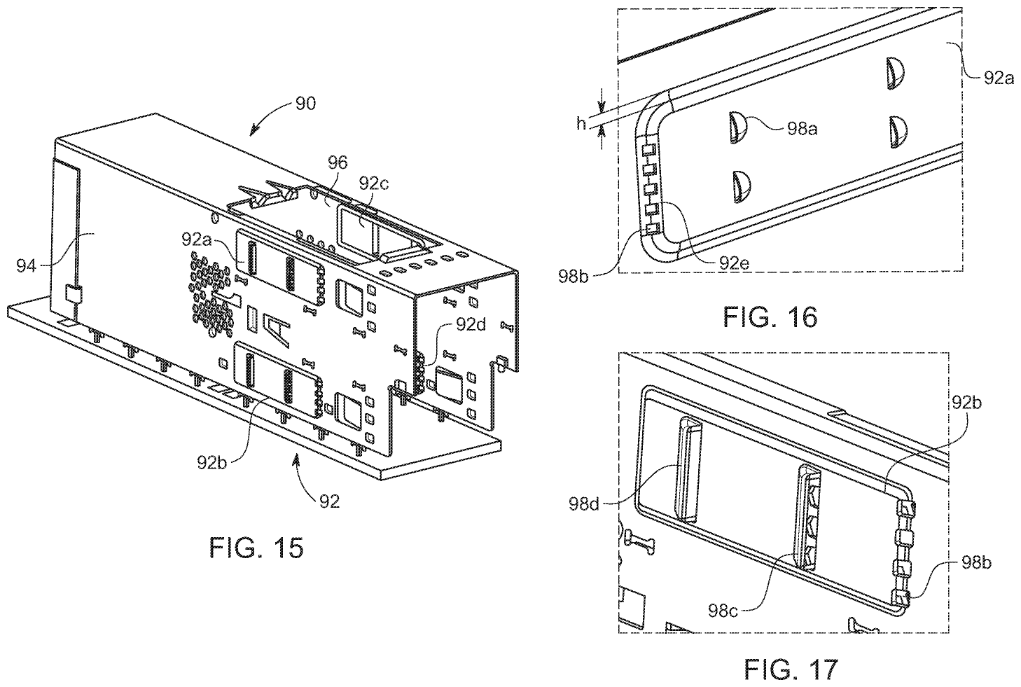

Another embodiment of a cage configured to improve air flow along inserted modules is shown in FIG. 15. As shown, a cage 90 is formed to include a set of raised pockets 92 incorporated within the structure of side walls 94, 96. A first pair of pockets 92a, 92b is shown as formed along side wall 94, and a second pair of pockets 92c, 92d formed along opposing side wall 96. Here, each pocket 92 comprises a raised, elongated section of the respective side wall, which functions to slightly increase the interior volume enclosed by cage 90, preferably along a portion of the sidewall adjacent to an inserted module. A plurality of air scooping structures 98 is formed along an exterior surface region of each raised pocket 92 to re-direct air flow from the exterior to the interior of cage 90 in the same manner as discussed above. The inclusion of raised pockets 92 creates an outwardly-protruding pocket edge 92e, shown in FIG. 16 as having a height h above the remainder of the side wall exterior surface, increasing the volume of “scooped” air and thus increasing the efficiency of the thermal energy transfer away from the inserted modules.

FIGS. 16 and 17 illustrate various exemplary configurations of air scooping structures 98 that may be included on the outer surface of pockets 92 (with the understanding that any suitable type of air scooping structure design may be used). For example, FIG. 16 shows a set of air scooping structures 98a shaped similar to protruding dimples 50 as shown in FIG. 5. An additional set of relatively small vents 98b is shown in this particular embodiment of FIG. 16 as formed along front edge 92e of pocket 92a. These vents may be used to further increase the volume of air re-directed from the exterior to the interior of the associated cage. Turning to FIG. 17, a raised pocket 92b is shown as including an air scooping structure comprising small vents 98b, as well as a pair of extended air diverters 98c that are similar to diverters 72 as discussed above in association with FIG. 10. If desired, the pockets 92 can also include a rear vent to allow air to flow out the pocket 92.

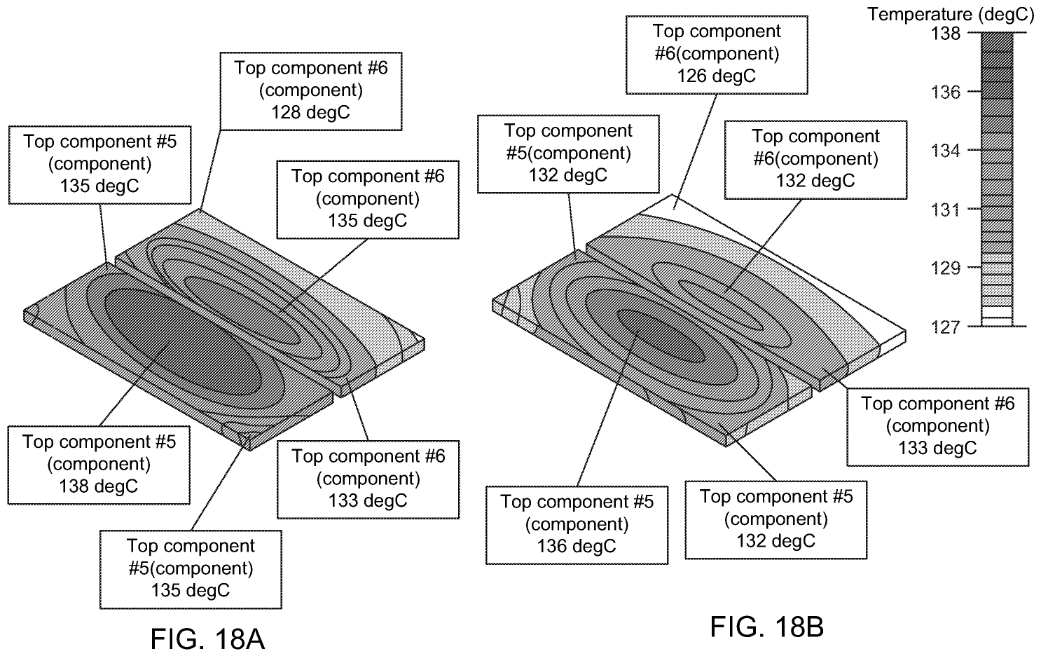

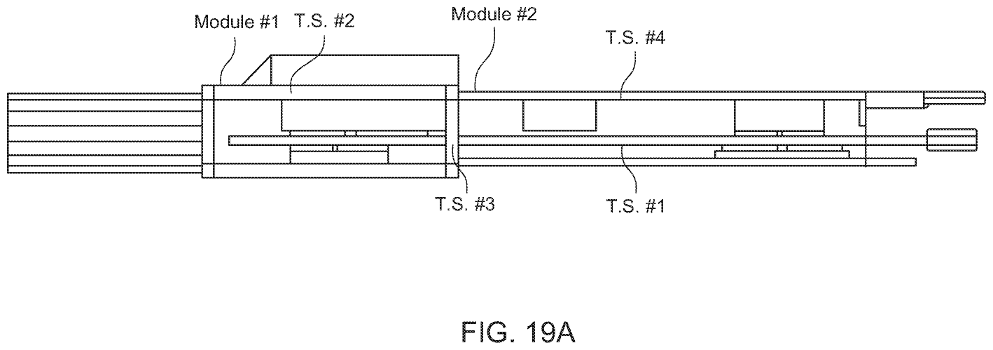

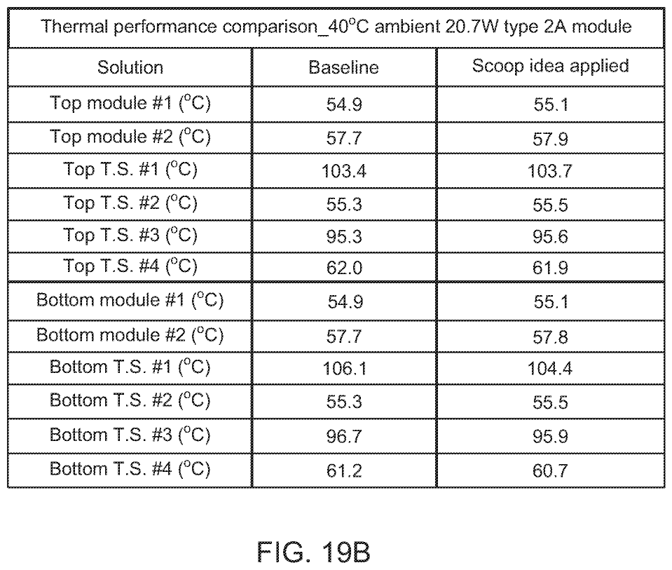

In terms of performance data, FIGS. 18(a), 18(b) includes a pair of heat maps showing temperature distribution across a top surface of a cage. The heat map of FIG. 18(a) is associated with a prior art connector assembly, where the temperature at selected locations across its surface is 135° C. or higher. In comparison, the heat map of FIG. 18(b) is associated with a cage configured to include the air flow structure of FIG. 7 (e.g., a diverter added over a set of side wall air holes). It is evident from a comparison of these heat maps that the improvement in air flow reduces the temperature at these same surface areas. The data related to these heat maps is contained in Table I of FIG. 19.

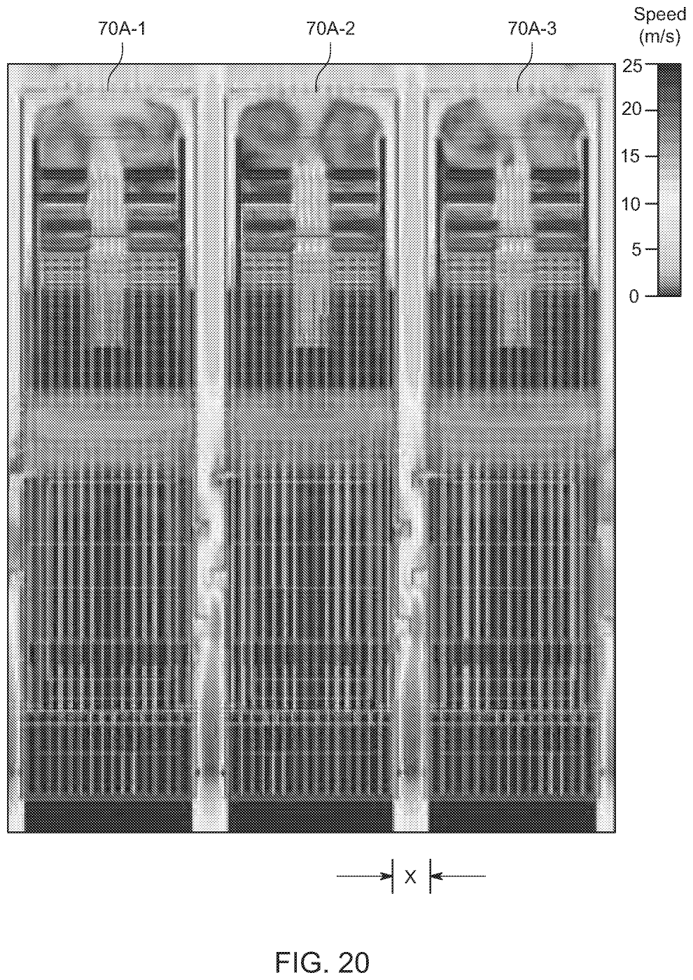

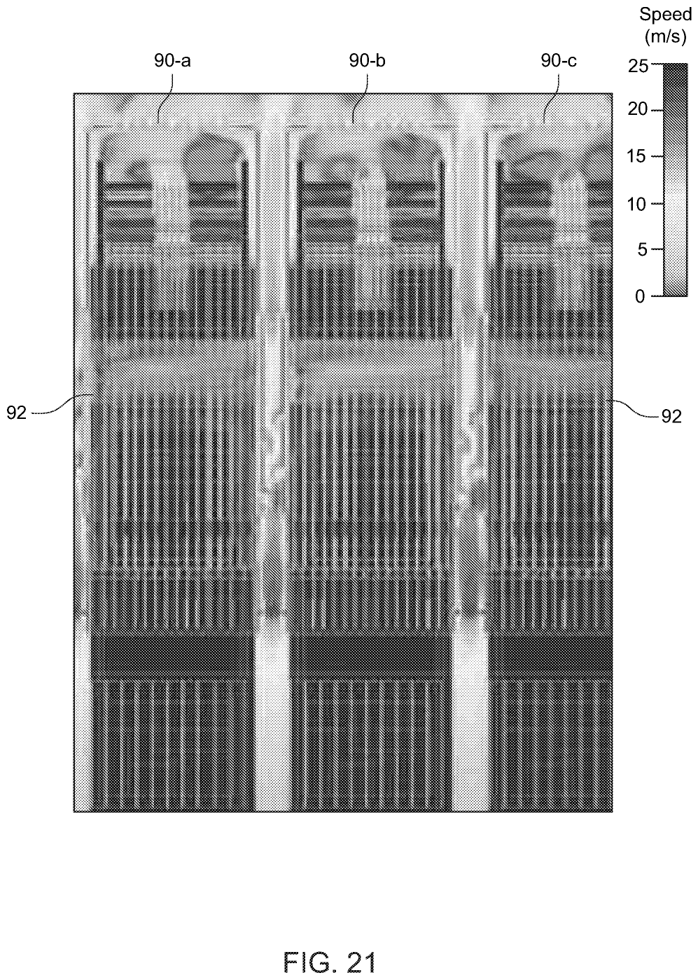

The staggered configuration of air diverters associated with a ganged set of cages, as shown in FIG. 14, has found to exhibit an improved the thermal performance of bottom port 30B by 0.6° C. FIG. 20 is a depiction of air flow across this embodiment of FIG. 14 and particularly illustrates the difference in air speed (m/s) created by including the staggered arrangement of air diverters.

As described above in association with FIG. 15, the incorporation of dimples has been found to further improve the thermal performance of the cage. FIG. 21 is a depiction of air flow through the embodiment of FIG. 15 (similar in form to that of FIG. 20), where the difference is the incorporation of the dimple geometry. By adding the dimple along with the scoops, the thermal performance of top port 30A increases by an additional 0.3° C., with bottom port 30B having a thermal performance increase of 0.7° C.

While the various scoop configurations as described above provide improve thermal performance, as evident by the results shown in FIGS. 19B-21, providing port cooling in the lower port of a stacked arrangement remains a significant challenge. In particular, the lack of spacing between the sidewalls of the cage and the connector housing has been found to block air flow beyond this point.

In accordance with another embodiment of the present disclosure, the side walls of the cage in the region of the connector housing are modified to include one or more offsets that slightly extend the width of the cage at this location (e.g., by a few mm) so as to enlarge the interior spacing between the connector housing and the sidewall.

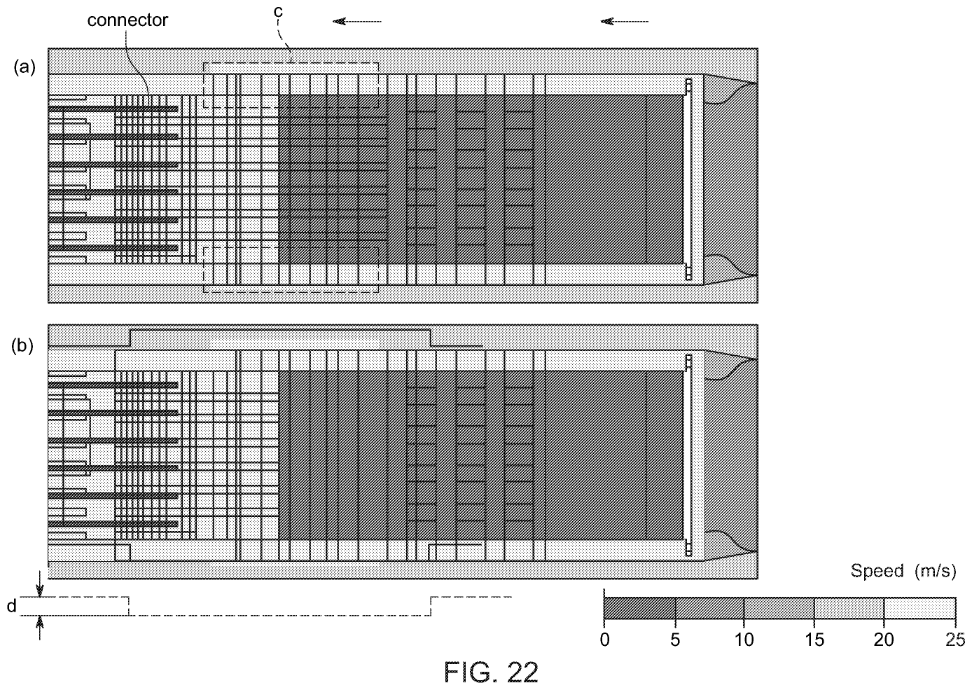

FIG. 22 contains a pair of air flow velocity maps that illustrate the improvement associated with the use of offsets. FIG. 22(a) illustrates air flow along a connector assembly from a port entrance, passing through the connector and then exiting along the rear wall. A pair of “choke points” C are shown as created in the region where the connector housing is essentially adjacent to the cage side walls. The presence of these choke points thus impede air flow. FIG. 22(b) shows the improvement in air flow that is found by including a pair of offsets 100 along the side walls of the cage in the vicinity of the connector housing. As will be described in detail below, offsets 100 (which may be formed to include vents) slight extend the width of the cage (each offset adding a gap of “d” on each side) in the area of the connector housing.

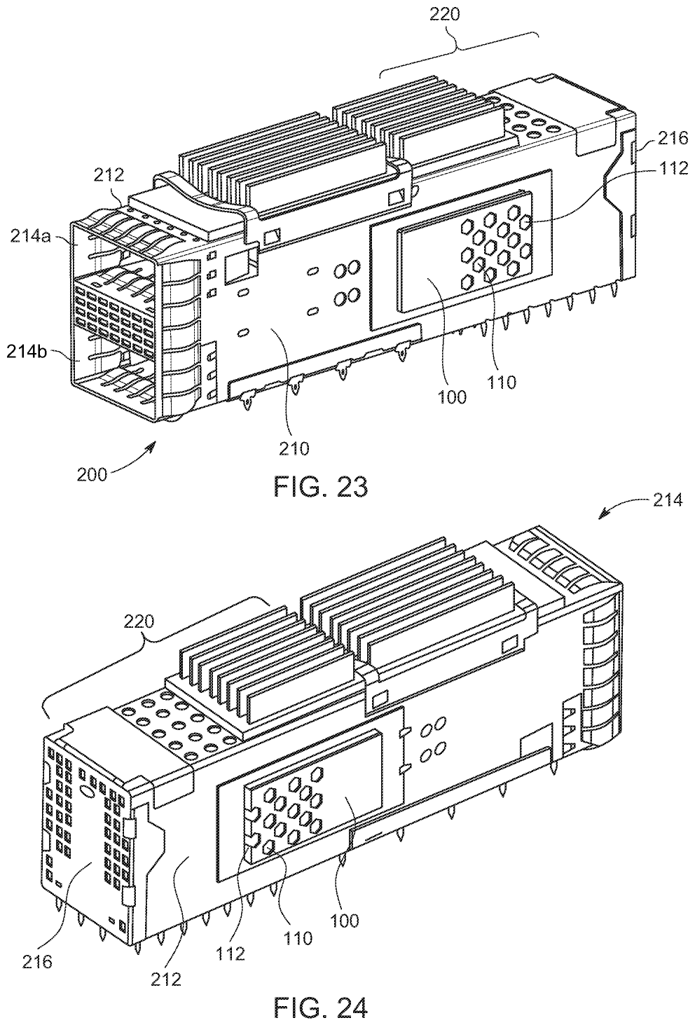

FIGS. 23 and 24 are isometric side views of an exemplary connector assembly formed to include a pair of offsets 100, where FIG. 23 illustrates a side view with the connector portion 220 of the assembly to the rear of the view and FIG. 24 illustrates a side view with the connector portion 220 to the front of the view. The connector assembly includes a cage 200 formed in the manner described above, and is defined as comprising a pair of opposing side walls 210, 212. A pair of ports 214A, 214B each accept an associated module. A rear wall 216 (through which the associated connector is placed in position in the connector assembly) is shown as including a number of vent holes that enable some air flow, but without the inclusion of offsets 100, the pinch points between the connector housing (not evident in this view) and side walls 210, 212 would remain problematic.

Thus, in further accordance with the present disclosure, it is proposed to supplement the above-described cage configurations with side wall offsets 100 that function to increase the spacing between side walls 210, 212 and the connector housing. In some embodiments, offsets 100 may be formed to include vents 110 and apertures 112 to provide additional paths for exhaust to move through the connector assembly.

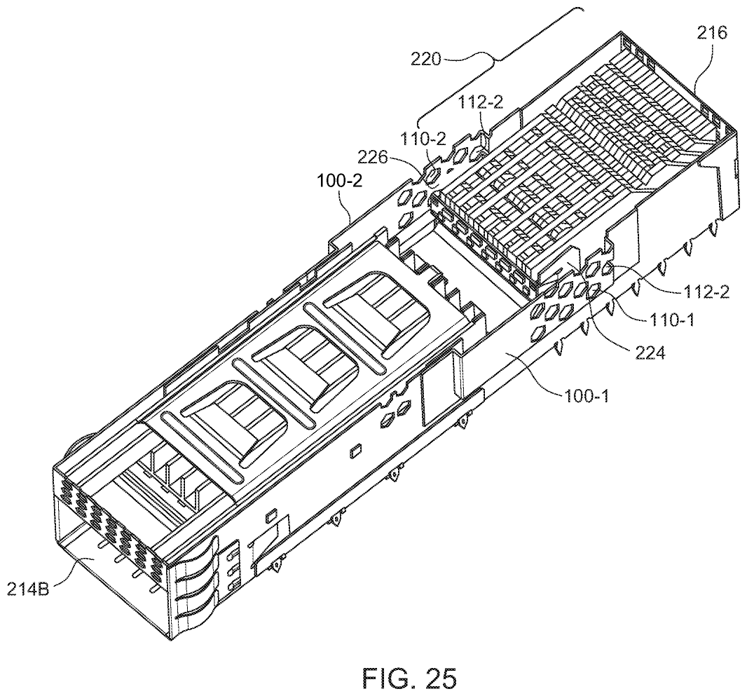

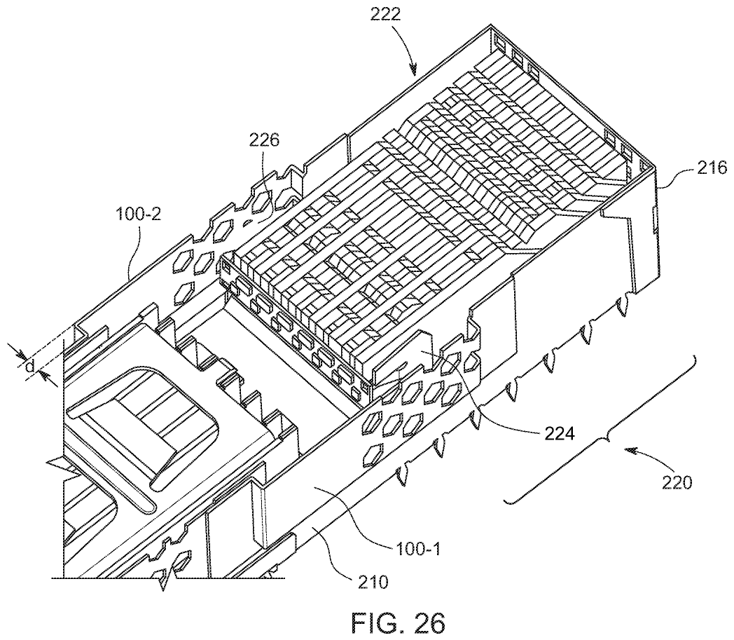

FIG. 25 is a cut-away view of the isometric side view of FIG. 23, which better illustrates the positioning of connector portion 220 within cage 200, as well as the relationship between offsets 100-1, 100-2 with connector portion 220. In particular, offsets 100-1, 100-2 are shown as positioned along cage side walls 210, 212 respectively, and function to widen cage 200 in the area where connector housing 222 is positioned. In particular, offset 100-1 is positioned to increase the gap spacing between side 224 of connector housing 222 and cage side wall 210. Similarly, offset 100-2 is positioned to increase the gap spacing between side 226 of connector housing 222 and cage side wall 212. FIG. 26 is an enlarged view of a portion of FIG. 25 and better illustrates the relative position of sides 224, 226 of connector housing 222 and offsets 100-100-2. It is to be understood that offsets 100 may be attached to the cage (via an adhesive or spot-welded or other desirable attachment approach) to cover openings created in a pair of original cage side walls. Alternatively, the cage side walls may be originally fabricated to include these offsets in the proper location along the length of the cage assembly.

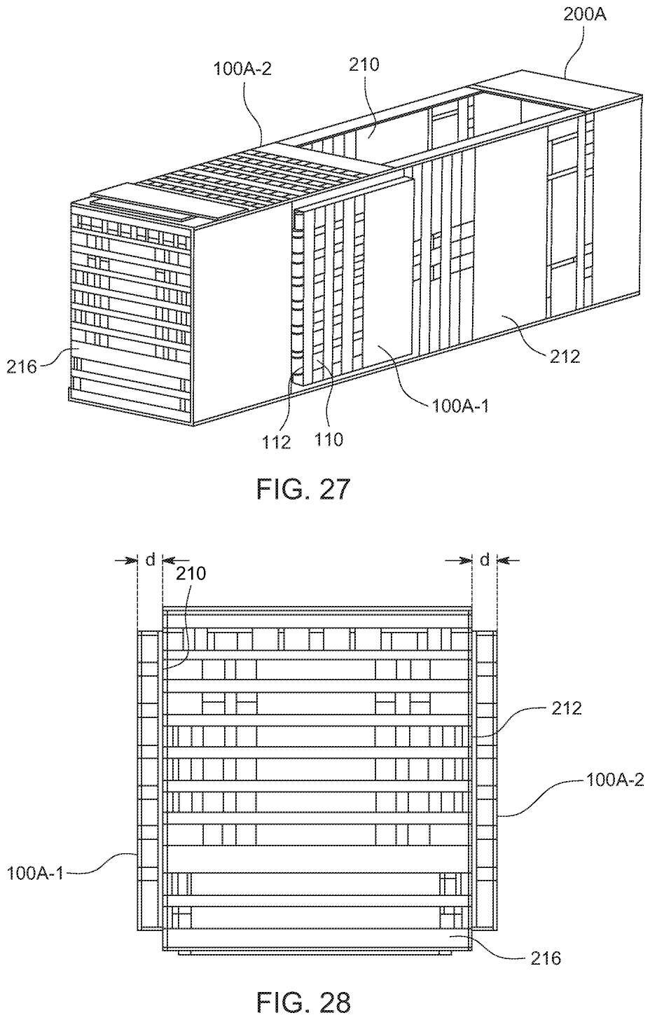

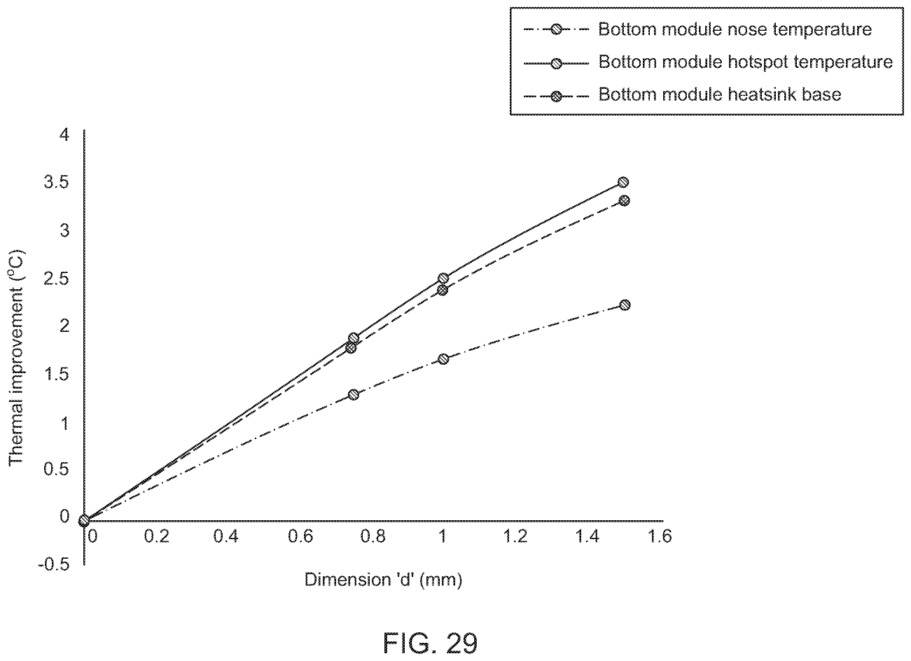

FIG. 27 is an isometric side view of a cage 200A (presenting rear wall 216 toward the front of the view) formed to include offsets 100A. Similar to the arrangement discussed above, offsets 100A may be added to cage 200A after its assembly, or formed directly in side walls 210, 212 in their manufacture. Again, vent holes 110, 112 may be included within offset 100A to provide additional avenues for exhaust to flow. FIG. 28 is an end view of cage 200A, particularly illustrating in this view the amount of offset “d” that is provided by the addition of the offset. Indeed, it has been found that the thermal performance of the bottom port region of a connector assembly increases with increasing offset dimension. FIG. 29 contains plots of thermal performance improvement, as a function of “d”, at three critical locations typically monitoring for thermal performance (i.e., “nose”, “hot spot”, and “heatsink base”). As can be appreciated, increasing “d” allows for increased performance but naturally is limited by the desire to position adjacent cages close together to ensure there is sufficient density of connections. As a result, it will rarely be desirable to have d exceed 1.5 mm and in many embodiments d can be in the range of 0.5-1.5 mm. As a result, the offset can be configured to provide an offset between the cage and the internal connector that provides a 0.5 mm gap or provides a 1.0 mm gap or a 1.5 mm gap or even a larger gap.

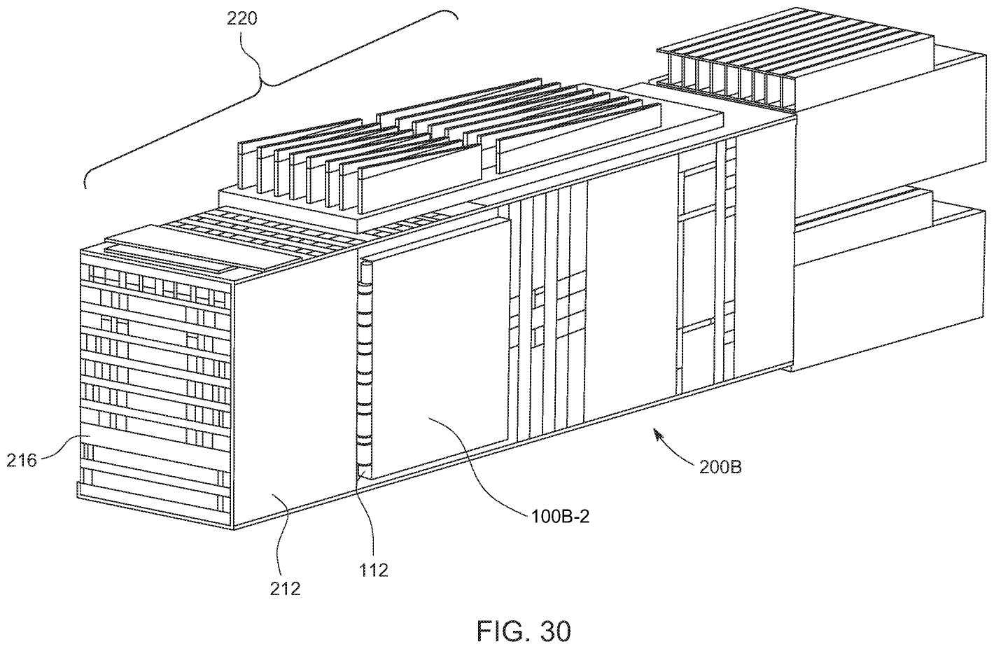

FIG. 30 contains an isometric side view of a connector assembly comprising a cage 200B and connector portion 220 (with associated modules 300 shown as inserted in this view). In this embodiment, a pair of offsets 100B are included to increase the gap spacing between the internal structure of connector portion 220 and side walls 210, 212 of cage 200B. In contrast to the embodiment of FIG. 27, offset 100B is formed as a solid plate without vent holes on the side and may only include optional apertures 112, as shown. The provision of offsets 100B provide the desired increase is spacing between connector portion 220 and cage side walls 210, 212, while the use of a solid plate is considered to improve the EMI shielding capability of the structure. Thus, depending on a particular application, it may be preferred to use a solid offset (for example, in very high frequency operation). The trade-offs between the use of vent holes (as well as their dimensions, placement, and the like) and the use of solid plates are considered to be design choices.

It can be seen that the cage assemblies of the present disclosure provide thermal energy dissipation for enclosed modules by air flow through scoop features formed on side walls of the cage structure. In addition, thermal dissipation can be improved by using an offset to reduce the choke point between the connector and the cage. Naturally, both features can be combined together as desired.

For example, a connector assembly could include a cage with scoops and an offset. In such an embodiment the scoops could be on one or both sides of the cage and could be staggered if desired. The offset could be vented or a solid place and also could be on one or both sides of the cage. Depending on the design of the connector assembly, the scoops might be only provided on the bottom port to help normalize the performance of the bottom port compared to the top port or could be provided on the top and bottom port. Naturally, another way to balance performance would be to use more scoop features on the bottom then on the top port.

While preferred embodiments of the present disclosure are shown and described, it is envisioned that those skilled in the art may devise various modifications without departing from the spirit and scope of the foregoing description and the appended claims.

The disclosure provided herein describes features in terms of preferred and exemplary embodiments thereof. Numerous other embodiments, modifications and variations within the scope and spirit of the appended claims will occur to persons of ordinary skill in the art from a review of this disclosure.

It will be appreciated that the foregoing description provides examples of the disclosed electrical connector assembly. However, it is contemplated that other implementations of the disclosure may differ in detail from the foregoing examples. All references to the disclosure or examples thereof are intended to reference the particular example being discussed at that point and are not intended to imply any limitations as to the scope of the disclosure more generally. Recitation of ranges of values herein are merely intended to serve as a shorthand method of referring individually to each separate value falling within the range, unless otherwise indicated herein, and each separate value is incorporated into the specification as it if were individually recited herein.

Accordingly, this disclosure includes all modifications and equivalents of the subject matter recited in the claims appended hereto as permitted by applicable law. Moreover, any combination of the above-described elements in all possible variations thereof is encompassed by the disclosure unless otherwise indicated herein or otherwise clearly contradicted by context. Still further, the advantages described herein may not be applicable to all embodiments encompassed by the claims.

While benefits, advantages, and solutions have been described above with regard to specific embodiments of the present disclosure, it should be understood that such benefits, advantages, and solutions and any element(s) that may cause or result in such benefits, advantages, or solutions, or cause such benefits, advantages, or solutions to become more pronounced are not to be construed as a critical, required, or an essential feature or element of any or all the claims appended to the present disclosure or that result from the present disclosure.

What is claimed is:

1. A connector assembly, comprising:
a cage formed of conductive material, the cage including a first side wall and a second side wall and a top wall that cooperatively define a port configured to receive and support an inserted module, the cage further including an opening through which the module may be inserted into, or removed from, port;
a connector positioned within the cage, the connector including a card slot aligned with the port; and
an air scooping structure formed along an exterior surface of the first side wall, the air scooping structure oriented to re-direct a flow of air into the port so as, in operation, to cause air flow across at least one surface of the inserted module so as to facilitate the removal of thermal energy from the inserted module.

2. The connector assembly of claim 1, wherein the second side wall includes an air scooping structure.

3. The connector assembly of claim 2, wherein each air scooping structure is positioned to be aligned with the location of an inserted module so as to be in close proximity to a thermal energy-generating element.

4. The connector assembly of claim 3, wherein the position of the air scooping structure on the first side wall is staggered with respect to the position of the air scooping structure on the second side wall.

5. The connector assembly of claim 1, wherein the air scooping structure comprises a protruding dimple including an aperture formed through the thickness of the first side wall, the aperture portion of the protruding dimple oriented to capture air flowing across the exterior surface of the first side wall.

6. The connector assembly of claim 5, wherein the air scooping structure comprises a plurality of protruding dimples arranged in a pattern on the first side wall of the cage.

7. The connector assembly of claim 1, wherein the air scoop comprises
a vent hole formed through the thickness of the first side wall; and
an air capture member disposed over the vent hole and positioned so as to re-direct a portion of an exterior air flow through the vent hole and into the port.

8. The connector assembly of claim 7 wherein a forward edge of the air capture member is positioned to overlap a forward edge of the vent hole.

9. The connector assembly of claim 7 wherein a forward edge of the air capture member is positioned in a non-overlapping configuration with a forward edge of the vent hole.

10. The connector assembly of claim 1, wherein the air scooping structure comprises
a plurality of air holes disposed in a defined arrangement along a portion of the first side wall; and
an air diverter disposed to span over the plurality of air holes and configured to re-direct a portion of an exterior air flow through the plurality of air holes and into the port.

11. The connector assembly of claim 10, wherein
the plurality of air holes are disposed in a linear, vertical arrangement along the at least one side wall of the cage; and
the air diverter comprises a combination of a top plate, a pair of opposing side edge plates, and a rear plate that forms an open face over the plurality of air holes, where the top plate comprises a length sufficient to completely span the linear, vertical arrangement of the plurality of air holes.

12. The connector assembly of claim 10, wherein the air diverter comprises a separate component attached to an exterior surface of the side wall of the cage.

13. The connector assembly of claim 12, wherein the air diverted is welded to the exterior surface of the side wall of the cage.

14. The connector assembly of claim 1, further comprising
a raised pocket region formed along the at least one side wall of the cage, wherein the air scooping structure is formed on an outer surface of the raised pocket region.

15. The connector assembly of claim 14, wherein the raised pocket region further comprises one or more vent holes formed along a raised front edge thereof for capturing additional exterior air flow.

16. The connector assembly of claim 1, wherein the connector includes an outer surface positioned adjacent an interior surface of one of the first and second walls, the cage further comprising a cage offset formed along an exterior surface of the one side wall, cage offset extending outward relative to the one wall so as to create a gap between the one side wall and the outer surface of the connector.

17. A connector assembly, comprising:
a cage including a first side wall and a second side wall opposing the first side wall and a top wall that cooperatively define an interior port configured to receive and support an inserted module, the cage further including an opening through which the module may be inserted into, or removed from, the port;
a connector positioned within the cage, the connector including a card slot aligned with the port for engaging with an inserted module; and
an air scooping structure formed along an exterior surface of at least one side wall at a location adjacent to the port and oriented to re-direct a flow of air into the interior of the cage so as to flow across at least one surface of the inserted module and facilitate the removal of thermal energy from the connector assembly.

18. A connector assembly comprising:
a cage including a plurality of walls that cooperatively define a first port and a second port, the first and the second ports configured to receive and support an inserted module, the cage further including an opening through which the first and second ports may be accessed;
a connector positioned within the cage, the connector including a card slot aligned with each of the ports; and
an air scooping structure formed along an exterior surface of a first side wall, the air scooping structure including a first set of air scoops positioned at a first location adjacent to the first port and oriented to re-direct a flow of air into the first port where an inserted module would be positioned and a second set of air scoops positioned at a second location adjacent the second port and oriented to re-direct a flow of air into the second port wherein an inserted module would be positioned.

19. A connector assembly, comprising:
a cage formed of conductive material, the cage including a first side wall and a second side wall opposite the first side wall and a top wall that cooperatively define a port configured to receive and support an inserted module, the cage further including an opening through which the module may be inserted into, or removed from, the port;
a connector positioned within the cage, the connector including a card slot aligned with the port; and
a cage offset formed along an exterior surface of the first side wall in proximity to the connector and configured to create an increased gap between the first side wall and an outer surface of the connector, the increased gap configured to improve air flow between the first side wall and the outer surface of the connector.

20. The connector assembly of claim 19, where a cage offset is formed along the second side wall.

21. The connector assembly of claim 19, wherein the cage offset is formed as a solid plate component.

22. The connector assembly of claim 19, wherein the cage offset is formed to include a plurality of vent holes.

23. The connector assembly of claim 19, wherein the cage offset comprises a separate component attached to an exterior surface of the first side wall.

24. The connector assembly of claim 23, wherein the cage offset is welded to the first side wall.

25. The connector assembly of claim 19, wherein the cage offset is directly formed in the first side wall.
